(19) United States
(12) Patent Application Publication
(10) Pub. No.: US 2015/0022979 A1
(43) Pub. Date: Jan. 22, 2015

(54) DISPLAY DEVICE

(71) Applicant: Samsung Display Co., Ltd., Yongin-City (KR)

(72) Inventors: Mi-Young Kang, Yongin-City (KR); Won-Gu Cho, Yongin-City (KR)

(21) Appl. No.: 14/142,447

(22) Filed: Dec. 27, 2013

(30) Foreign Application Priority Data
Jul. 16, 2013 (KR) 10-2013-0083778

(51) Int. Cl. H05K 1/02; H05K 5/00

(52) U.S. Cl. CPC H05K 1/028; H05K 5/0017
USPC 361/749

(57) ABSTRACT

A display device according to an exemplary embodiment of the present invention includes: a display panel displaying an image; a window disposed on a first surface of the display panel; a first cover film disposed on a second surface of the display panel; a flexible printed circuit (FPC) disposed under the first cover film; a flexible printed circuit film connecting the display panel and the flexible printed circuit (FPC); and a second cover film disposed under the first cover film and the flexible printed circuit film. The second cover film and the flexible printed circuit film are adhered by an adhesive.

### CLAIM OF PRIORITY

This application makes reference to, incorporates the same herein, and claims all benefits accruing under 35 U.S.C. §119 from an application earlier filed in the Korean Intellectual Property Office on 16 Jul. 2013 and there duly assigned Serial No. 10-2013-0083778.

### BACKGROUND OF THE INVENTION

1. Field of the Invention

An embodiment of the present invention relates to a display device, and more specifically, to a display device preventing a phenomenon in which a flexible printed circuit film extending from a front surface to a rear surface of a display device is reflected to appear as a stain.

2. Description of the Related Art

As currently popular display devices, there are a liquid crystal display device (LCD), a plasma display device (PDP), an organic light emitting display device (OLED), a field effect display device (FED), and an electrophoretic display device (EPD).

The display device generally includes a display panel displaying images, and a cover film protecting the display panel is disposed under the display panel. Also, a flexible printed circuit (FPC) receiving a signal from the outside is disposed on the cover film.

A flexible printed circuit film is connected to the flexible printed circuit (FPC), and a cover flexible printed film to protect the flexible printed circuit film connected to the flexible printed circuit (FPC) is attached. With such structure, a phenomenon in which the flexible printed circuit film is reflected on a front surface of the display device like a stain may occur.

The above information disclosed in this Background section is only for enhancement of understanding of the background of the invention and therefore it may contain information that does not form the prior art that is already known in this country to a person of ordinary skill in the art.

### SUMMARY OF THE INVENTION

An aspect of the present invention is to prevent the phenomenon in which a flexible printed circuit film extending from a front surface to a rear surface of a display device is reflected to appear as a stain.

A display device according to an exemplary embodiment of the present invention includes: a display panel displaying an image; a window disposed on a first surface of the display panel; a first cover film disposed on a second surface of the display panel; a flexible printed circuit (FPC) disposed under the first cover film; a flexible printed circuit film connecting the display panel and the flexible printed circuit (FPC); and a second cover film disposed under the first cover film and the flexible printed circuit film. The second cover film and the flexible printed circuit film are adhered by an adhesive.

The flexible printed circuit (FPC) may be connected to an extension of the flexible printed circuit film.

The second cover film may be adhered to the extension of the flexible printed circuit film.

The first cover film and the second cover film may be formed of the same material.

An area of the first cover film may be wider than an area of the second cover film.

A display device according to an exemplary embodiment of the present invention may further include a polarizing plate disposed between the display panel and the window.

A display device according to an exemplary embodiment of the present invention may further include a touch panel disposed between the polarizing plate and the window.

A display device according to an exemplary embodiment of the present invention may further include a driving chip disposed on the flexible printed circuit film.

A display device according to an exemplary embodiment of the present invention includes: a display panel displaying an image; a window disposed on a first surface of the display panel, the image displayed through the window; a first cover film disposed on a second surface of the display panel, with the second surface disposed opposite to the first surface; a second cover film disposed on the second surface of the display panel, with the second cover film disposed farther from the display panel in comparison with the first cover film; a flexible printed circuit (FPC) disposed between the first cover film and the second cover film; and a flexible printed circuit film connecting the display panel and the flexible printed circuit (FPC), a fraction of the flexible printed circuit film disposed between the flexible printed circuit (FPC) and the second cover film, and the second cover film and the fraction of the flexible printed circuit film being adhered together.

An end portion of the flexible printed circuit film is disposed between the flexible printed circuit (FPC) and the second cover film. According to an exemplary embodiment of the present invention, through the structure in which the flexible printed circuit film connected to the flexible printed circuit (FPC) is attached to the second cover film, the phenomenon that the flexible printed circuit film is reflected like a stain on the front surface of the display device may be prevented.

### BRIEF DESCRIPTION OF THE DRAWINGS

A more complete appreciation of the invention, and many of the attendant advantages thereof, will be readily apparent as the same becomes better understood by reference to the following detailed description when considered in conjunction with the accompanying drawings in which like reference symbols indicate the same or similar components, wherein:

FIG. 1 is a cross-sectional view of a display device according to an exemplary embodiment of the present invention.

FIG. 2 is a view of a bottom surface of the display device of FIG. 1.

FIG. 3 is a cross-sectional view taken along the line III-III of FIG. 2.

FIG. 4A is a picture of a contemporary display device, and FIG. 4B is a picture of a display device according to an exemplary embodiment of the present invention.

### DETAILED DESCRIPTION OF THE EMBODIMENTS

Exemplary embodiments of the present invention will be described in detail with reference to the attached drawings. The present invention may be modified in many different forms, and should not be construed as being limited to the exemplary embodiments set forth herein. Rather, the exemplary embodiments of the present invention are provided so that this disclosure will be thorough and complete, and will fully convey the concept of the present invention to those skilled in the art.

In the drawings, the thickness of layers and regions may be exaggerated for clarity. In addition, when a layer is described to be formed on another layer or on a substrate, this means that the layer may be formed on the other layer or on the substrate, or a third layer may be interposed between the layer and the other layer or the substrate Like numbers refer to like elements throughout the specification.

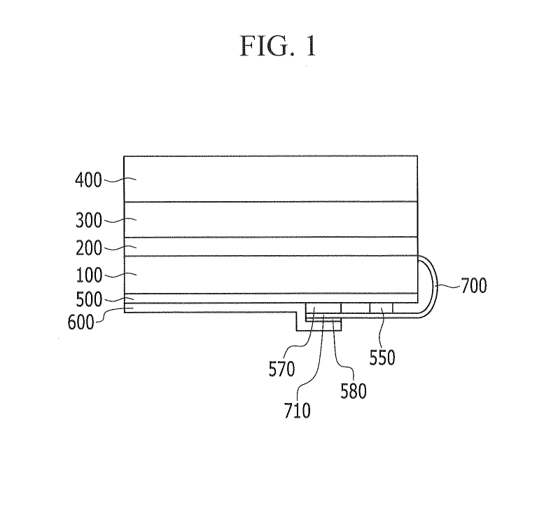

A display device according to an exemplary embodiment of the present invention will now be described with reference to FIG. 1 through FIG. 3.

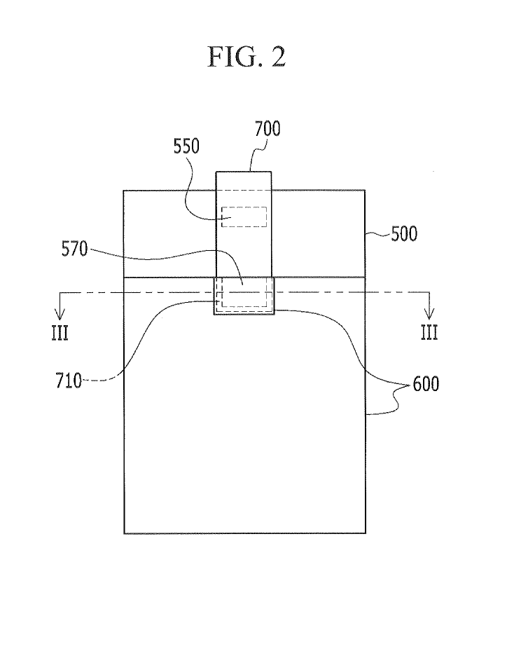

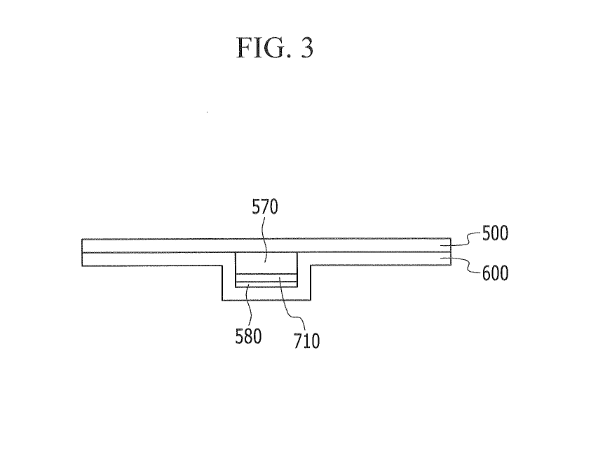

FIG. 1 is a cross-sectional view of a display device according to an exemplary embodiment of the present invention, FIG. 2 is a view of a bottom surface of the display device of FIG. 1, and FIG. 3 is a cross-sectional view taken along the line of FIG. 2.

In reference to FIG. 1 through FIG. 3, the display device according to the present exemplary embodiment includes a display panel 100, and a polarizing plate 200, a touch panel 300, and a window 400 that are sequentially disposed on a first surface of the display panel 100.

The display device according to the present exemplary embodiment also includes a first cover film 500 disposed on a second surface of the display panel 100, a flexible printed circuit (FPC) 570 disposed under the first cover film 500, and a second cover film 600 disposed under the first cover film 500 and the flexible printed circuit (FPC) 570.

The display device according to the present exemplary embodiment further includes a flexible printed circuit film 700 connecting the flexible printed circuit (FPC) 570 and the display panel 100. A driving chip 550 is disposed on the flexible printed circuit film 700.

The display panel 100 as a constituent element for displaying an image may be an organic light emitting display panel including an organic light emitting element, a liquid crystal display panel, a plasma display panel (PDP), an electric field effect display panel, or an electrophoretic display panel. Also, the display panel 100 may be a flexible panel.

The polarizing plate 200 converts a light axis of light emitted outside through the display panel 100. The polarizing plate 200 may be formed in a structure in which a transparent protection film is layered to both sides or one side of a polarizer that is formed of a polyvinyl alcohol-based resin.

The touch panel 300 senses an outer touch. The touch panel 300 may be a resistive type, a capacitive type, a photosensor type, or an electromagnetic type.

The window 400 protects the touch panel 300 and the display panel 100.

The first cover film 500 is disposed under the display panel 100 to protect the display panel 100. The first cover film 500 is formed of a black color to prevent reflection of light. The first cover film 500 may have a function of buffering an impact applied to the display device from below. It may be formed of a black material having an impact-absorbing characteristic.

The flexible printed circuit (FPC) 570 receives a video signal from the outside and transmits the video signal to the display panel 100. The flexible printed circuit (FPC) 570 is connected to an extension 710 of the flexible printed circuit film 700, thereby transmitting the video signal from the outside to the display panel through the flexible printed circuit film 700. The flexible printed circuit (FPC) 570 may be connected to the extension 710 of the flexible printed circuit film 700 through an anisotropic conductive film (ACF).

The extension 710 of the flexible printed circuit film 700 is connected to the flexible printed circuit (FPC) 570 such that the video signal transmitted from the outside is transmitted to the display panel 100. The video signal transmitted from the outside generates a driving signal in the driving chip 550 of the flexible printed circuit film 700 to be transmitted to the display panel 100.

The driving chip 550 may be disposed on the display panel 100. The flexible printed circuit film 700 transmits the video signal transmitted from the outside to the driving chip 550 disposed on the display panel 100. Alternatively, the driving signal may be generated in the driving chip 550 and may be transmitted to the display panel 100.

The second cover film 600 is disposed on the first cover film 500 and on the extension 710 of the flexible printed circuit film 700. The second cover film 600 to protect and fix the extension 710 of the flexible printed circuit film 700 connected to the flexible printed circuit (FPC) 570 is adhered to the extension 710 of the flexible printed circuit film 700 by an adhesive 580.

The first cover film 500 and the second cover film 600 are made of the same material, and an area of the first cover film 500 is bigger than an area of the second cover film 600. As shown in FIG. 2, in the extending direction of the flexible printed circuit film 700, the length of the first cover film 500 is bigger than the length of the second cover film 600.

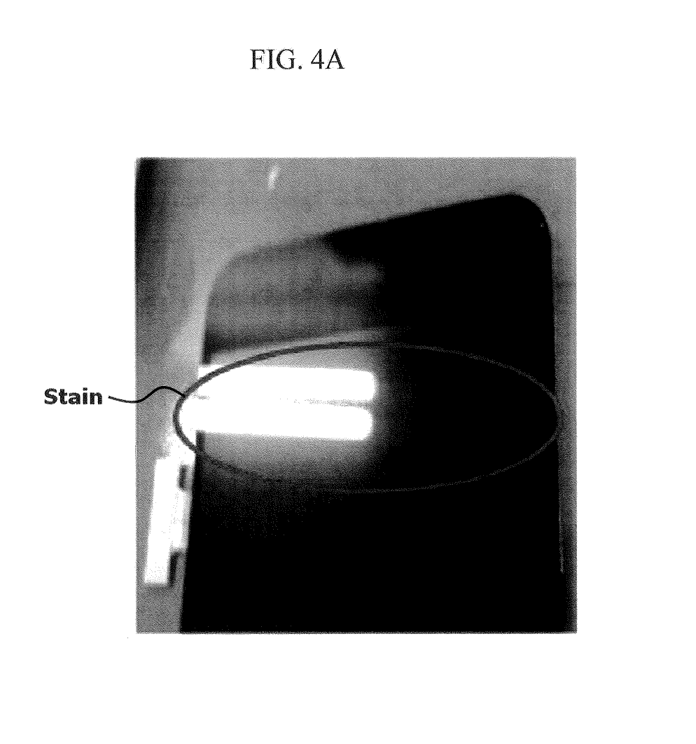

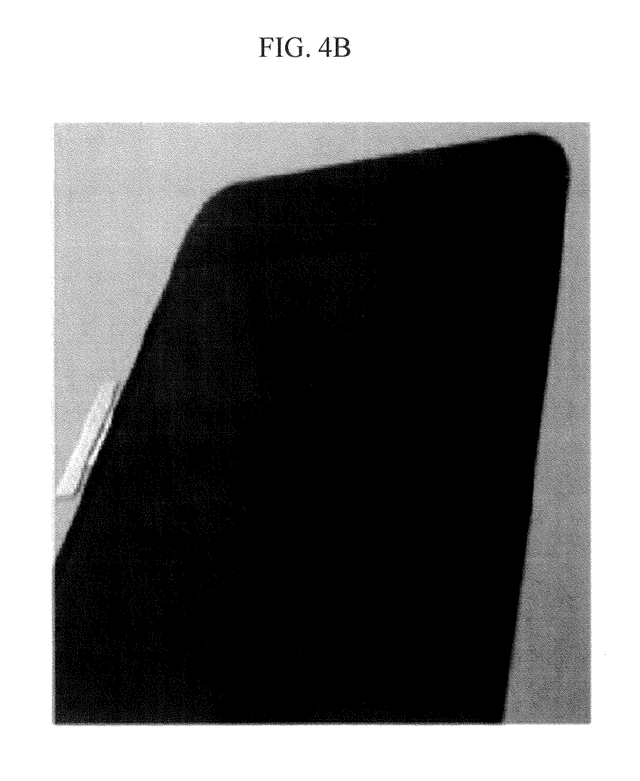

In reference to FIG. 4A and FIG. 4B, a display device according to an exemplary embodiment of the present invention and a contemporary display device will be compared.

FIG. 4A is a picture of a contemporary display device, and FIG. 4B is a picture of a display device according to an exemplary embodiment of the present invention.

In reference to FIG. 4A and FIG. 4B, stains appear in the contemporary display device, however it is confirmed that the stains are eliminated in the display device according to an exemplary embodiment of the present invention.

As described above, by protecting and fixing the extension 710 of the flexible printed circuit film 700 by using the second cover film 600 made of the same material as the first cover film 500, the phenomenon that the flexible printed circuit film 700 is reflected like the stain may be prevented.

While this invention has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

### Description of Symbols

| | |
|---|---|
| 100: display panel | 200: polarizing plate |
| 300: touch panel | 400: window |
| 500: first cover film | 550: driving chip |
| 570: flexible printed circuit (FPC) | 580: adhesive |
| 600: second cover film | 700: flexible printed circuit film |

What is claimed is:

1. A display device comprising:
a display panel displaying an image;
a window disposed on a first surface of the display panel;
a first cover film disposed on a second surface of the display panel;
a flexible printed circuit (FPC) disposed under the first cover film;
a flexible printed circuit film connecting the display panel and the flexible printed circuit (FPC); and
a second cover film disposed under the first cover film and the flexible printed circuit film, wherein the second cover film and the flexible printed circuit film are adhered together by an adhesive.

2. The display device of claim 1, wherein the flexible printed circuit (FPC) is connected to an extension of the flexible printed circuit film.

3. The display device of claim 2, wherein the second cover film is adhered to the extension of the flexible printed circuit film.

4. The display device of claim 1, wherein the first cover film and the second cover film are formed of a same material.

5. The display device of claim 4, wherein an area of the first cover film is bigger than an area of the second cover film.

6. The display device of claim 1, further comprising a polarizing plate disposed between the display panel and the window.

7. The display device of claim 6, further comprising a touch panel disposed between the polarizing plate and the window.

8. The display device of claim 7, further comprising a driving chip disposed on the flexible printed circuit film.

9. A display device, comprising:
a display panel displaying an image;
a window disposed on a first surface of the display panel, the image displayed through the window;
a first cover film disposed on a second surface of the display panel, with the second surface disposed opposite to the first surface;
a second cover film disposed on the second surface of the display panel, with the second cover film disposed farther from the display panel in comparison with the first cover film;
a flexible printed circuit (FPC) disposed between the first cover film and the second cover film; and
a flexible printed circuit film connecting the display panel and the flexible printed circuit (FPC), a fraction of the flexible printed circuit film disposed between the flexible printed circuit (FPC) and the second cover film, and the second cover film and the fraction of the flexible printed circuit film being adhered together.

10. The display device of claim 9, wherein an end portion of the flexible printed circuit film is disposed between the flexible printed circuit (FPC) and the second cover film.

11. The display device of claim 9, wherein the first cover film and the second cover film are formed of a same material.
